(19) United States
(12) Patent Application Publication
(10) Pub. No.: US 2004/0031148 A1
(43) Pub. Date: Feb. 19, 2004

(54) Connection method

(76) Inventor: Frank Tyldesley, Cambridge (GB)

Correspondence Address: ALIX YALE & RISTAS LLP, 750 MAIN STREET, SUITE 1400, HARTFORD, CT, 06103, US

(21) Appl. No.: 10/363,457

(22) PCT Filed: Aug. 22, 2001
(86) PCT No.: PCT/GB01/03799

(30) Foreign Application Priority Data
Sep. 4, 2000 (GB) 00217505

(51) Int. Cl. H05K 3/10; H01R 43/00; C09J 1/00; H01H 1/00

(52) U.S. Cl. 29/854; 29/877; 29/593; 29/846; 156/295

(57) ABSTRACT

A printed circuit board (7) is electrically connected to an electroluminescent display by applying the circuit board (7) to the display so that metal tracks (8) on the underside of the circuit bard (7) make electrical contact with conductive tracks (6) on the display. While the tracks (6, 8) are in electrical contact and electrically insulating adhesive (10) is applied between the lower surface of the circuit board (7) and the upper surface of the display to bond the circuit board (7) to the display. The thickness of the tracks (6, 8) spaces the circuit board (7) from the display to define a void to receive the adhesive (10). The connection method has the advantage that the operation of the assembled circuit board (7) and display can be tested before the adhesive is applied.

The present invention relates to a method of connecting electrical components, which is of particular utility for making connections to electroluminescent displays.

Electroluminescence is the emission of light by a material when subjected to an electric field.

A typical thick film phosphor electroluminescent device comprises a layer of electroluminescent material in a dielectric matrix, sandwiched between two planar conducting electrodes. The electroluminescent material comprises phosphor particles, typically a zinc sulphide (ZnS) powder doped with manganese (Mn), microencapsulated in a dielectric material. Typically, silver- or graphite-loaded screen-printable inks, and. indium tin oxide (ITO), a transparent conductive material, respectively are used to form the electrodes on a substrate such as a polyester film. When an AC voltage is applied between the electrodes, the electroluminescent material emits light.

The inventors have recently developed thick film electroluminescent displays in which a plurality of shaped independent electrodes are provided on at least one side of a layer of electroluminescent material. A voltage may be applied selectively to each of these independent electrodes to illuminate a respective region of the display. A thick film electroluminescent display is created by selecting the configuration of the independent electrodes to represent information, for example in the form of a seven-segment display or the like.

A problem associated with the manufacture of thick film electroluminescent displays is that the independent electrodes must be connected electrically to a voltage source for the display. In a convenient manufacturing technique, electrical connections are applied as conductive tracks on the rear surface of the device, for example by screen printing conductive ink. However, for the display to operate, each conductive track must be connected electrically to a selectively operable voltage source. In even a relatively simple display, the number of connections that must be made is quite large and it is desirable for these connections to be made in as small an area as possible. Furthermore, the connections need to be made reliably.

In printed circuit board manufacture, it is known to connect components to the circuit board by bonding with electrically conductive adhesive. In such bonding methods, electrically conductive adhesive is register printed onto specific contact areas. The components are then accurately placed on the contact areas and held in place while the adhesive is cured. The curing process is typically a ten minute heat cure in an oven, during which the assembled component and circuit board have to be kept flat and stable. The adhesive will conduct electricity once it has been cured and the bond has been made. At this point, the electrical connection between the component and the circuit board can be tested.

U.S. Pat. No. 4,749,120 discloses a process for bonding a semiconductor device to a circuit board composed of a glass, ceramic or resin substrate with a conductive gold or indium tin oxide (ITO) circuit pattern thereon. According to this method, an insulating synthetic resin is disposed on the circuit board where the semiconductor device is to be attached. The semiconductor device is pressed onto the resin and metal bumps on the underside of the semiconductor device displace the resin to make electrical contact with the circuit pattern. In this position, light or heat is applied to cure the resin, which then holds the semiconductor device in place and maintains the electrical contact.

The present invention provides a method for connecting electrical components comprising:

providing a first component having a first surface with a plurality of electrically conductive first regions;

providing a second component having a second surface with a plurality of electrically conductive second regions each arranged for electrical connection to a respective first region;

applying the first component to the second component such that the first regions make electrical contact with the second regions; and

while the first regions and the second regions are in electrical contact, applying an electrically insulating adhesive between the first surface and the second surface to bond the first component to the second component;

wherein the first regions project from the first surface, such that when the first and second regions are in electrical contact the first surface is spaced from the second surface and thereby at least one void is defined between the two surfaces to receive the adhesive.

Thus, according to the invention the insulating adhesive is applied between the surfaces of the components after electrical contact has been made between the first and second regions. This means that the electrical connections between the components can be tested before adhesive is applied to the components. This has the advantage that if the testing of the electrical connection reveals that one of the components is faulty, that component can be discarded independently of the other component, which reduces the overall cost due to faulty components.

If testing reveals that both components operate properly and the correct electrical connections have been made between them, the adhesive can be applied between the components to bond them together. In this way, the components can be bonded together in exactly the position in which it has been demonstrated that the correct electrical connections have been made, so that it is certain that the electrical connections will function properly after bonding.

The adhesive can be applied between the components after electrical contact has been established because the first regions act to space the surfaces of the components and provide room for the adhesive. In this way, the need for additional spacers is obviated which leads to a simplified construction of the first component, while ensuring a reliable electrical connection. Furthermore, it is not necessary to push connectors through the adhesive as in prior art connection methods so there is no risk that the adhesive will interfere with the electrical connection by becoming interposed between the first and second regions.

The method may explicitly include the additional step of testing the electrical connection between the first regions and the second regions before the adhesive is applied. The invention allows the testing to be carried out on the unbonded components while they are in the position in which they will be bonded.

Optionally, the method may include the step of testing the operation of the connected first and second components before the adhesive is applied. For example, the connection of the first and second components may be one of the final steps in a more complex manufacturing process and the method of the invention allows the operation of the assembled components to be tested before finally bonding the components together.

The first and second components may be any suitable components. For example, the first and/or second component may be a printed circuit board (PCB) or an individual semiconductor package or the like. In the preferred arrangement, the first or second component is an electroluminescent display, and the other component is a printed circuit board.

The electroluminescent display may comprise a transparent, and preferably flexible, substrate provided with a transparent front electrode layer, such as a layer of indium tin oxide (ITO). The substrate may be of any suitable material, for example polyester or polyethylene teraphthalate (PET).

A layer of electroluminescent phosphor, such as manganese-doped zinc sulphide, may be provided on the substrate. The electroluminescent phosphor may be applied to the substrate by screen printing or any other suitable method.

A rear electrode layer may be provided over the electroluminescent phosphor, so that an alternating voltage can be applied between the rear electrode layer and the front electrode layer to cause the electroluminescent phosphor to illuminate, in use. The rear electrode layer may be applied to the electroluminescent phosphor by screen printing, or other suitable application, of a conductive, for example silver-loaded, ink.

The rear electrode layer may be configured into discrete regions or segments which form a display of selectively illuminable portions of the electroluminescent phosphor. The alternating voltage may be supplied to the segments of the electrode layer, in use, by conductive tracks, which may be spaced from the electrode layer by a dielectric layer to prevent the voltage being applied to undesired segments of the electrode layer. The transparent electrode layer and/or the electroluminescent phosphor may be configured into discrete regions which form a display of selectively illuminable portions of the electroluminescent phosphor.

The configuration of the display is generally such that information can be represented by the display by the application of a voltage to selected portions of the rear electrode layer. For example the areas that can be illuminated may be arranged in a numeric or alphanumeric display arrangement, such as a seven, fourteen or sixteen segment display.

The rear electrode segments may be provided on the display by any suitable method, such as by screen printing with conductive, for example silver- or graphite-loaded, inks.

The electrically-conductive tracks may be formed on the device by any suitable method, such as by screen printing with conductive, for example silver- or graphite-loaded, inks. Feasibly, some electrically-conductive tracks may be formed on the device together with the rear-electrode segments. In this case, these electrically-conductive tracks may be considered as an extension of the relevant rear-electrode segments. At least part of the electrically-conductive tracks may be integral with the rear-electrode segments.

In general, a respective electrically-conductive track is provided for each rear-electrode segment.

The conductive tracks may be printed onto areas of the display substrate from which the transparent conductor, e.g. ITO, layer has been removed. The conductive tracks may be printed on top of other layers of the electroluminescent device.

The method of the invention may be used to connect more than two components.

The first and second surfaces may take any suitable form. In general, the second surface is substantially complementary to the first surface. In the preferred arrangement, the first and second surfaces are substantially flat, being the surfaces of the electroluminescent display and of the printed circuit board.

The second regions may project from the second surface in a similar manner to the first regions projecting from the first surface. In this way, a greater spacing can be achieved between the first and second surfaces when the first and second regions are in electrical contact.

The first and/or second regions may be in the form of a layer of electrically conductive material applied to the respective first or second surface. Thus, the contact surfaces of the first (second) regions may be substantially parallel to the first (second) surface. In the preferred embodiment, the first or second regions are formed by terminal portions of conductive tracks on the electroluminescent display or on the printed circuit board. In this way, the first or second regions can be formed as part of the normal production process for the display or circuit board without requiring an additional production step.

Screen printing of the conductive tracks produces a raised pattern with a thickness of 10 to 30 microns, typically about 20 microns. Etching, during the production of printed circuit boards leaves a corresponding raised pattern. The PCB contact thickness is normally in the range 15 to 50 microns. The projections formed by screen printing or etching have a consistent and well-defined thickness.

In general, the first and/or second regions are formed as an ordered array. In particular, the spacing between adjacent first (and second) regions may be such that passageways for the adhesive are formed between the first (and second) regions when the first and second regions are in electrical contact. In this way, the first (and second) regions act to guide the flow of adhesive when it is applied to the assembled components.

In a particularly preferred arrangement, the configuration of the first (and second) regions is such that capillary passages are formed between the first (and second) regions when they are in electrical contact which draw the adhesive between the components by capillary action.

Thus, the adhesive may be applied between the components by capillary action. In this case, the adhesive may be selected to have an appropriate viscosity to achieve the necessary capillary action. Alternatively, the adhesive may be injected between the components. The components may be formed with holes or passageways through which the adhesive is injected in order to ensure that the adhesive is evenly distributed between the components. Projections which do not make electrical contact may be provided on the components, e.g. the display and the printed circuit board, to guide the flow of adhesive as it is added or injected.

The adhesive may be any suitable material, for example a UV cured resin. Other suitable types of adhesive are two part, thermoset, reactive, and hot melt adhesives. The presently preferred adhesive material is Virtalit 504-16-2, a UV-cure material from Eurobond Adhesives. This material gives a good combination of toughness and strength.

The adhesive may be UV-cured by shining UV light through the transparent front face of the electroluminescent display. However, the adhesive could be activated using a chemical activator to allow it to be used for bonding to an opaque fronted display or to opaque regions of the display.

After the first component has been applied to the second component, the components may be held together mechanically, for example by means of a clamp or jig.

Some embodiments of the invention will now be described by way of example only, and with reference to the accompanying drawings, in which:

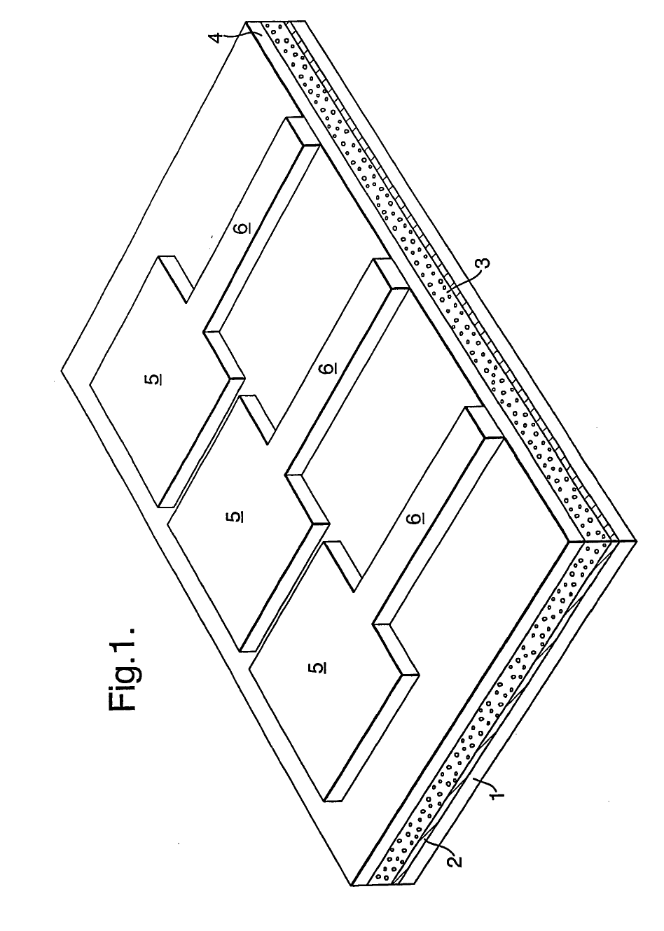

FIG. 1 is a schematic representation of a simplified electroluminescent display; and

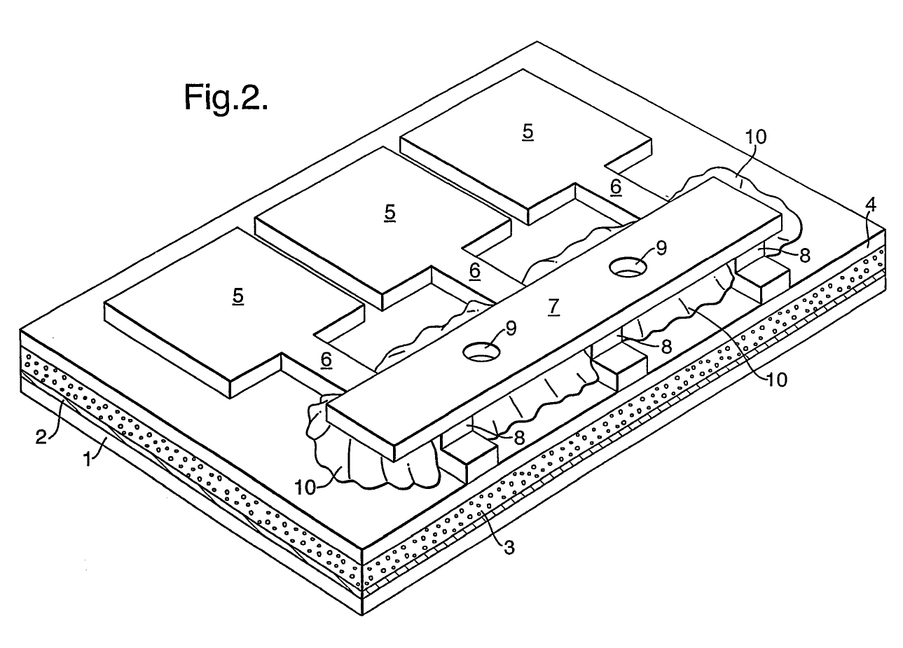

FIG. 2 is a schematic representation of the electroluminescent display of FIG. 1 connected to a circuit board in accordance with the invention.

As shown in FIG. 1 an electroluminescent display comprises a substrate layer 1 of transparent PET, which is prefabricated with a layer of indium tin oxide (ITO) 2 to form a transparent front electrode. A layer of thick film electroluminescent phosphor material 3 is provided on top of the ITO layer 2. A dielectric layer 4 is provided over the phosphor layer 3. On top of the dielectric layer 4 is provided a rear electrode in the form of a plurality (three in FIG. 1) of electrode segments 5 of screen-printed silver-loaded ink. A respective electrically conductive track 6 extends from each electrode segment 5 to the edge of the display. In the example shown in FIG. 1, the conductive tracks 6 are shown as integral with the electrode segments 5 for simplicity, although this is not necessarily the case in a practical display.

In use, an AC driving voltage of 100 to 600 volts is applied between an electrode segment 5 via the conductive track 6 and the ITO layer 2, in order to generate an electric field across the electroluminescent phosphor 3 so that the phosphor emits light in the region covered by the particular electrode segment 5. The selective provision of the driving voltage to the electrode segments 5 is controlled by a printed circuit board 7 which is connected to the display as shown in FIG. 2.

Referring to FIG. 2, the printed circuit board 7 which is shown in a very simplified form for reasons of clarity is provided on its lower surface with metal tracks 8 which correspond substantially in shape and position to the conductive tracks 6 on the display. The metal tracks 8 on the printed circuit board are connected to electronic components (not shown) which generate and control the driving voltage for the display.

In order to connect the printed circuit board 7 to the display, the circuit board 7 is located with the metal tracks 8 in electrical contact with the conductive tracks 6 in the position shown in FIG. 2. The circuit board 7 is pressed against the display to ensure good electrical contact between the metal tracks 8 and the conductive tracks 6. At this stage, the circuit board 7 may be activated and the correct operation of the assembled circuit board 7 and display tested to ensure that neither component is faulty and that the correct electrical connections have been made.

As can be seen from FIG. 2, the thickness of the conductive tracks 6 and the metal tracks 8 spaces the lower surface of the circuit board 7 from the upper surface of the dielectric layer 4, when the tracks 6, 8 are in electrical contact. According to the invention, the void thus formed is filled with electrically insulating adhesive 10 which bonds the circuit board 7 to the display and maintains the electrical contact between the tracks 6, 8.

The adhesive 10 can be applied by injection through holes 9 formed through the circuit board 7. Alternatively, the adhesive can be applied along the edge of the circuit board 7, so that capillary action draws the adhesive 10 into the void between the lower surface of the circuit board 7 and the upper surface of the dielectric layer 4. Once the adhesive has been applied between the circuit board 7 and the display, the adhesive 10 is cured, for example with UV light.

In summary, a printed circuit board 7 is electrically connected to an electroluminescent display by applying the circuit board 7 to the display so that metal tracks 8 on the underside of the circuit board 7 make electrical contact with conductive tracks 6 on the display. While the tracks 6, 8 are in electrical contact an electrically insulating adhesive 10 is applied between the lower surface of the circuit board 7 and the upper surface of the display to bond the circuit board 7 to the display. The thickness of the tracks 6, 8 spaces the circuit board 7 from the display to define a void to receive the adhesive 10. The connection method has the advantage that the operation of the assembled circuit board 7 and display can be tested before the adhesive is applied.

1. A method for connecting electrical components comprising:
providing a first component having a first surface with a plurality of electrically conductive first regions;
providing a second component having a second surface with a plurality of electrically conductive second regions each arranged for electrical connection to a respective first region;
applying the first component to the second component such that the first regions make electrical contact with the second regions; and
while the first regions and the second regions are in electrical contact, applying an electrically insulating adhesive between the first surface and the second surface to bond the first component to the second component;
wherein the first regions project from the first surface, such that when the first and second regions are in electrical contact the first surface is spaced from the second surface and thereby at least one void is defined between the two surfaces to receive the adhesive.

2. A method as claimed in claim 1 further comprising testing the electrical connection between the first and second components before applying the adhesive.

3. A method as claimed in claim 1 or 2, wherein one of the first component and the second component is an electroluminescent display.

4. A method as claimed in any preceding claim, wherein the first regions are in the form of a layer of electrically conductive material applied to the first surface.

5. A method as claimed in any preceding claim, wherein the first regions are arranged to form capillary passageways when the first and second regions are in electrical contact to draw the adhesive between the components by capillary action.
